(19) United States
(12) Patent Application Publication
(10) Pub. No.: US 2008/0180910 A1
(43) Pub. Date: Jul. 31, 2008

(54) Portable Electronic Apparatus

(75) Inventor: Kentaro Tomioka, Sayama-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/016,532

(22) Filed: Jan. 18, 2008

(30) Foreign Application Priority Data
Jan. 30, 2007 (JP) 2007-020017

(51) Int. Cl. H05K 7/20

(52) U.S. Cl. 361/695

(57) ABSTRACT

According to one embodiment, a portable electronic apparatus includes a casing provided with an exhaust hole part, a printed circuit board contained in the casing, an exothermic body mounted on the printed circuit board, a first cooling fan and a second cooling fan which are contained in the casing. The casing contains an upper space extending above the printed circuit board and a lower space extending below the printed circuit board. The first cooling fan is arranged in the upper space, and is provided with an inlet port opened in the upper space, and an exhaust port directed to the exhaust hole part. The second cooling fan is arranged in the lower space, and is provided with an inlet port opened in the lower space, and an exhaust port directed to the exhaust hole part.

### CROSS-REFERENCE TO RELATED APPLICATIONS

This application is based upon and claims the benefit of priority from Japanese Patent Application No. 2007-020017, filed Jan. 30, 2007, the entire contents of which are incorporated herein by reference.

### BACKGROUND

1. Field

One embodiment of the invention relates to a portable electronic apparatus provided with a plurality of cooling fans.

2. Description of the Related Art

A portable electronic apparatus such as a portable computer is generally provided with a cooling fan in a casing. Jpn. Pat. Appln. KOKAI Publication No. 2000-349475, disclosed an electronic apparatus provided with a fan for cooling circuit components mounted on a printed circuit board. The cooling fan includes an upper rotor and a lower rotor which are arranged separately from each other on both sides of the printed circuit board. The upper rotor is provided with a front fan section. The lower rotor is provided with a bottom fan section. The upper rotor and the lower rotor are coupled to each other through a rotor shaft provided so as to penetrate the printed circuit board.

According to such a cooling fan, a stator needed to rotate the cooling fan can be directly mounted on the printed circuit board, and hence the space necessary for arranging the cooling fan can be made small.

When a cooling fan is mounted on a portable electronic apparatus, normally, a cutout hole slightly larger than the cooling fan is formed in the printed circuit board. The cooling fan is disposed in this cutout hole, and is arranged on the printed circuit board in the horizontal direction. Such a printed circuit board is limited in the board area due to the formation of the cutout hole, leading to increased complication in wiring design, mounting limitation of circuit components, and increased complication in the layer structure.

Further, when the ventilation resistance of the upper space which extends above the printed circuit board and that of the lower space which extends below the printed circuit board differ from each other in such a portable electronic apparatus, the cooling fan draws much air from the space having the smaller ventilation resistance, and draws little air from the space having the larger ventilation resistance. In other words, it cannot be said that cooling in the region having the larger ventilation resistance is sufficiently promoted.

It is conceivable that a predetermined amount of air can be drawn from the space having the larger ventilation resistance by increasing the intake air amount, e.g., by increasing the rotational speed of the cooling fan. However, if the rotational speed of the cooling fan is increased, more air than necessary is drawn from the space having the lower ventilation resistance, which is no more useful, and increases the noise.

In the cooling fan described in the above Pat. Document, the front fan section and the bottom fan section are coupled to each other through the rotor shaft. Accordingly, the rotational speed of the front fan section and that of the bottom fan section are identical with each other at all times. By using such a cooling fan, the flow of air flowing along the upper surface of the printed circuit board and that flowing along the lower surface of the printed circuit board become substantially the same as each other. In other words, if the upper surface side and the lower surface side of the printed circuit board differ from each other in the ventilation resistance or required discharge rate, it cannot be said that the optimum cooling operation can be realized.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary cross-sectional view of a portable computer according to the first embodiment;

FIG. 3 is an exemplary cross-sectional view of the portable computer shown in FIG. 2 taken along line F3-F3;

FIG. 4 is an exemplary view showing relationships between the fan characteristics, impedance of portable electronic apparatus, and air flow rate;

FIG. 5 is an exemplary cross-sectional view of a modification example of the portable computer according to the first embodiment;

FIG. 6 is an exemplary cross-sectional view of a portable computer according to a second embodiment of the present invention;

FIG. 7 is an exemplary cross-sectional view of a portable computer according to a third embodiment of the present invention;

FIG. 8 is an exemplary cross-sectional view of the portable computer shown in FIG. 7 taken along line F8-F8;

FIG. 9 is an exemplary cross-sectional view of a portable computer according to a fourth embodiment of the present invention; and

FIG. 10 is an exemplary cross-sectional view of a portable computer according to a fifth embodiment of the present invention.

### DETAILED DESCRIPTION

Various embodiments according to the invention will be described hereinafter with reference to the accompanying drawings. In general, according to one embodiment of the invention, a portable electronic apparatus includes a casing provided with an exhaust hole part, a printed circuit board contained in the casing, an exothermic body mounted on the printed circuit board, a first cooling fan and a second cooling fan which are contained in the casing. The casing contains an upper space extending above the printed circuit board and a lower space extending below the printed circuit board. The first cooling fan is arranged in the upper space, and is provided with an inlet port opened in the upper space, and an exhaust port directed to the exhaust hole part. The second cooling fan is arranged in the lower space, and is provided with an inlet port opened in the lower space, and an exhaust port directed to the exhaust hole part.

Embodiments of the present invention will be described below on the basis of drawings in which the embodiments are applied to portable computers.

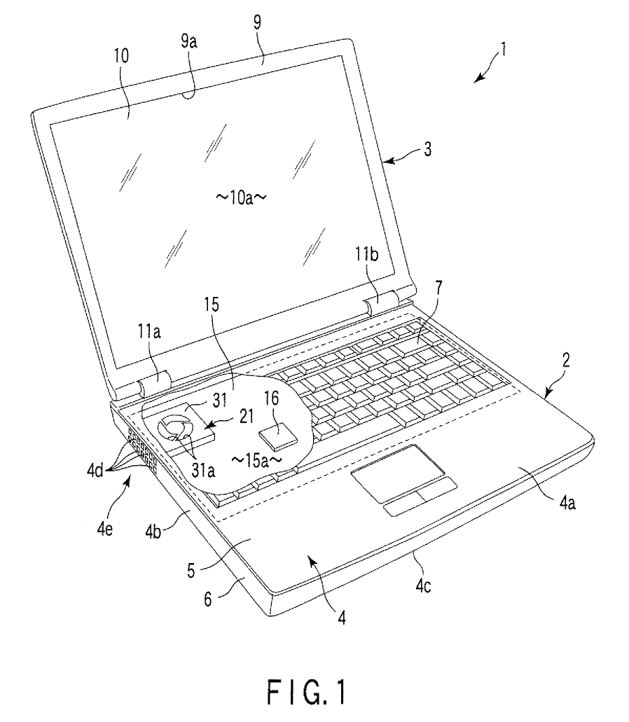

FIGS. 1 to 3 show a portable computer 1 which is a portable electronic apparatus according to a first embodiment of the present invention. As shown in FIG. 1, the portable computer 1 is provided with a main body 2 and a display unit 3.

As shown in FIG. 1, the main body 2 includes a casing 4 formed into a box-like shape. The casing 4 includes an upper wall 4a, peripheral walls 4b, and a bottom wall 4c. The casing 4 is divided into, for example, a casing cover 5 including the upper wall 4a, and a casing base 6 including the bottom wall 4c. The casing cover 5 is combined with the casing base 6 from above, and is detachably supported on the casing base 6. The upper wall 4a supports a keyboard 7. On the peripheral wall 4b, a exhaust hole part 4e is provided. The exhaust hole part 4e includes, for example, a plurality of exhaust holes 4d which are opened on the peripheral wall 4b.

The display unit 3 is provided with a display housing 9, and a liquid crystal display module 10 contained in the display housing 9. The liquid crystal display module 10 includes a display screen 10a. The display screen 10a is exposed to the outside of the display housing 9 through an opening formed at the front of the display housing 9.

The display unit 3 is supported at the rear end part of the casing 4 through a pair of hinge sections 11a and 11b. As a result, the display unit 3 can be moved between a closed position, in which the display unit is laid flat so as to cover the upper wall 4a from above, and an open position, in which the display unit 3 is raised so as to expose the upper wall 4a.

As shown in FIG. 1, a printed circuit board 15 is contained in the casing 4 of the main body 2. An exothermic body 16 is mounted on the printed circuit board 15. Examples of the exothermic body 16 are a CPU, graphics chip, Northbridge®, and memory. Incidentally, the exothermic body to which the present invention can be applied is not limited to the above examples, and corresponds to various circuit components which generate heat at the time of use and for which heat radiation is desirable. Further, various circuit components (i.e., electronic components) 17 which generate heat at the time of use are mounted on the upper surface 15a and the lower surface 15b of the printed circuit board 15 (see FIG. 3).

As shown in FIG. 3, the casing 4 contains an internal space. The internal space of the casing 4 includes an upper space S1 extending above the printed circuit board 15 and a lower space S2 extending below the printed circuit board 15. In other words, the space inside the casing 4 is partitioned into the upper space S1 and the lower space S2 by the printed circuit board 15. Incidentally, the upper space S1 mentioned in the present invention includes not only the space between the upper wall 4a and the printed circuit board 15 but also the space outside the region of the printed circuit board 15, as long as the space S1 extends above the printed circuit board 15. Likewise, the lower space S2 mentioned in the present invention includes the space outside of the region of the printed circuit board 15, as long as the space S2 extends below the printed circuit board 15.

The printed circuit board 15 is an example of a printed circuit board that is upwardly decentered in respect of the center of the internal space of the casing 4 in the thickness direction of the printed circuit board 15 (i.e., in the vertical direction in FIG. 3). In other words, the upper space S1 and the lower space S2 differ from each other in size. Because of the difference in size between the upper space S1 and the lower space S2, and other various mounting structures inside the casing 4, the upper space S1 and the lower space S2 have ventilation resistance values different from each other. For example, in this embodiment, the ventilation resistance of the upper space S1 is larger than that of the lower space S2. Incidentally, the printed circuit board 15 is not necessarily decentered.

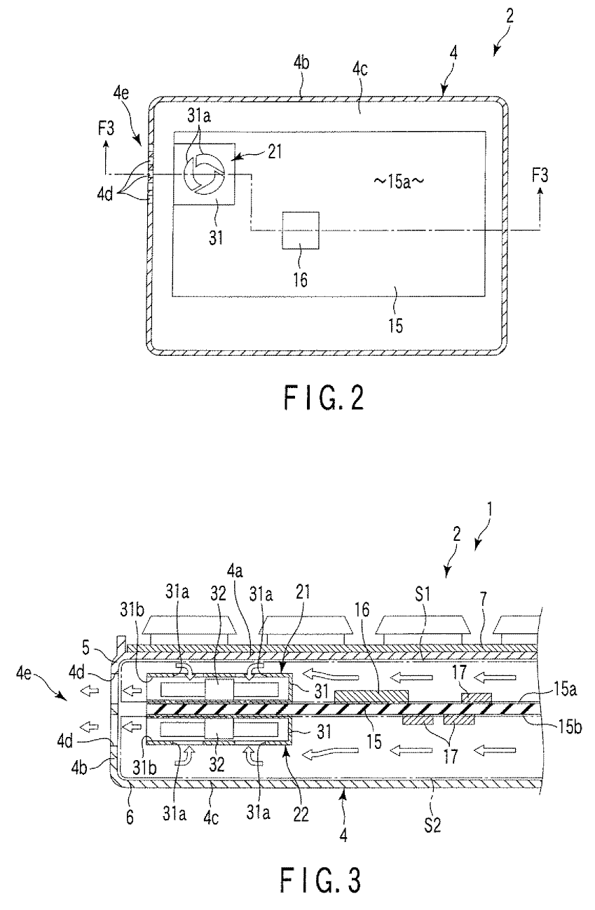

As shown in FIG. 3, the casing 4 contains therein first and second cooling fans 21 and 22. The first cooling fan 21 is arranged in the upper space S1. The first cooling fan 21 overlaps with the printed circuit board 15 in the thickness direction of the printed circuit board 15, and is opposed to the printed circuit board 15 from above. As shown in FIGS. 2 and 3, the first cooling fan 21 overlaps with the printed circuit board 15 in its entirety.

The first cooling fan 21 includes a fan case 31, and an impeller 32 driven to be rotated inside the fan case 31. The first cooling fan 21 is a thin type centrifugal fan. The fan case 31 is provided with inlet ports 31a and an exhaust port 31b. The inlet ports 31a are formed in the upper surface of the fan case 31, and are opened in the upper space S1. The exhaust port 31b is formed in the side surface of the fan case 31, and is directed to the exhaust holes 4d of the exhaust part 4e of the casing 4.

The first cooling fan 21 inhales air in the upper space S1 from the inlet ports 31a, and discharges the inhaled air through the exhaust port 31b toward the exhaust holes 4d of the casing 4. As an example of the first cooling fan 21, a cooling fan having the performance sufficient to exhaust the air in the upper space S1 to the outside of the casing 4, and promote cooling of the upper space S1 is selected.

As shown in FIG. 3, the second cooling fan 22 is arranged in the lower space S2. The second cooling fan 22 overlaps with the printed circuit board 15 in the thickness direction of the printed circuit board 15, and is opposed to the printed circuit board 15 from below (i.e., in the direction opposite to the first cooling fan 21). The second cooling fan 22 overlaps with the printed circuit board 15 in its entirety.

The second cooling fan 22 includes a fan case 31, and an impeller 32 driven to be rotated inside the fan case 31. The second cooling fan 22 is a thin type centrifugal fan. The fan case 31 is provided with inlet ports 31a and an exhaust port 31b. The inlet ports 31a are formed in the lower surface of the fan case 31, and are opened in the lower space S2. The exhaust port 31b is formed in the side surface of the fan case 31, and is directed to the exhaust holes 4d of the exhaust part 4e of the casing 4.

The second cooling fan 22 inhales air in the lower space S2 from the inlet ports 31a, and discharges the inhaled air through the exhaust port 31b toward the exhaust holes 4d of the casing 4. As an example of the second cooling fan 21, a cooling fan having the performance sufficient to exhaust the air in the lower space S2 to the outside of the casing 4, and promote cooling of the lower space S2 is selected.

As shown in FIG. 3, the printed circuit board 15 is interposed between the first and the second cooling fans 21 and 22, and the first and the second cooling fans 21 and 22 overlap with each other vertically in the thickness direction of the printed circuit board 15. The first and the second cooling fans 21 and 22 according to this embodiment are fixed to the printed circuit board 15. However, one of or both the first and the second cooling fans 21 and 22 may be fixed to the casing 4.

The printed circuit board 15 includes a control section for controlling the first and the second cooling fans 21 and 22. When, for example, the cooling amount necessary for the lower space S2 is smaller than the cooling amount necessary for the upper space S1, the second cooling fan 22 is driven at a speed lower than that of the first cooling fan 21 or is stopped. Likewise, when for example, the cooling amount necessary for the upper space S1 is smaller than the cooling amount necessary for the lower space S2, the first cooling fan 21 is driven at a speed lower than that of the second cooling fan 22 or is stopped. The first and the second cooling fans 21 and 22 are controlled to be driven respectively in accordance with their necessary cooling amount.

Next, the function of the portable computer 1 will be described below.

When the portable computer 1 is used, the exothermic body 16 generates heat and the various circuit components 17 also generate heat. Part of the heat generated by the exothermic body 16 is discharged to the inside of the casing 4, and remaining part of the heat is transmitted to the printed circuit board 15. On the printed circuit board 15, a wiring pattern formed by using, for example, a copper foil is provided. The heat transmitted to the printed circuit board 15 extends over the printed circuit board 15 through the wiring pattern and the like. Due to the presence of these heat components, the air in the upper space S1 in the casing 4 and the air in the lower space S2 is warmed.

The black outline arrows in FIG. 3 show the airflow. When the first cooling fan 21 is driven, the first cooling fan 21 inhales the warmed air in the upper space S1, and discharges the inhaled air to the outside of the casing 4 through the exhaust holes 4d of the casing 4. As a result, cold air flows into the upper space S1 through intake holes (not shown) provided on the casing 4, and cooling of the exothermic body 16 mounted on the upper surface 15a of the printed circuit board 15 is promoted.

When the second cooling fan 22 is driven, the second cooling fan 22 inhales the warmed air in the lower space S2, and discharges the inhaled air to the outside of the casing 4 through the exhaust holes 4d of the casing 4. As a result, cold air flows into the lower space S2, and cooling of the circuit components 17 mounted on the lower surface 15b of the printed circuit board 15 is promoted.

According to the portable computer 1 configured as described above, the board area of the printed circuit board 15 can be secured, and a high cooling performance can be realized. That is, by mounting the two cooling fans 21 and 22 separately on both the surfaces of the printed circuit board 15, it becomes unnecessary to form a cutout hole for mounting of the cooling fan in the printed circuit board 15. Accordingly, it is possible to secure a large board area of the printed circuit board 15 without being hindered by the cooling fan. If the board area of the printed circuit board 15 is increased, it is possible to shorten the wiring design period, improve the function of the printed circuit board 15 owing to an increase in the number of the mounting components, and simplify the layer structure of the printed circuit board 15.

When the two cooling fans 21 and 22 are separately arranged on both the surfaces of the printed circuit board 15, it is possible to sufficiently cool the components mounted on the upper surface 15a of the printed circuit board 15 and the components mounted on the lower surface 15b thereof. As a result, even when the board area of the printed circuit board 15 is secured, a high cooling performance can be realized.

By separately providing the cooling fan 21 for cooling the upper surface 15a of the printed circuit board 15 and the cooling fan 22 for cooling the lower surface 15b thereof, when for example, it is desired to cool only the upper surface 15a of the printed circuit board 15, only the cooling fan 21 of the upper surface 15a side needs be driven, and the cooling fan 22 of the lower surface 15b side can be stopped. In other words, by controlling the two cooling fans 21 and 22 separately from each other, it is possible to cool a part which needs to be cooled as much as needed. As a result of this, it is possible to reduce the energy required and noise.

Depending on the structure of the casing 4 and the component arrangement in the casing 4, the upper space S1 and the lower space S2 normally differ from each other in ventilation resistance. Particularly, when the printed circuit board 15 is decentered from the center of the space in the casing 4, as in this embodiment, the upper space S1 and the lower space S2 differ from each other in ventilation resistance. By separately arranging cooling fans 21 and 22 in the upper space S1 and in the lower space S2, respectively, it is possible to control the drive of the cooling fans 21 and 22 according to whether the ventilation resistance is large or small.

Incidentally, FIG. 5 shows an example of a modification of this embodiment. As shown in FIG. 5, at least a part of one of the first and the second cooling fans 21 and 22 may overlap with the printed circuit board 15. In such a portable computer 1, the board area of the printed circuit board 15 can be secured, and a high cooling performance can be realized. However, when the printed circuit board 15 is provided up to a region in which both the first and second cooling fans 21 and 22 overlap with the printed circuit board 15 as shown in FIG. 3, a larger board area of the printed circuit board 15 can be secured.

When the first and second cooling fans 21 and 22 overlap with each other, the parts constituting the cooling structure are collectively mounted at a part in the casing 4, and hence the mounting density in the casing 4 can be improved, and a dead space can be reduced. Incidentally, the first and second cooling fans 21 and 22 may overlap with each other in their entirety or may overlap with each other only partly.

Further, when the first and second cooling fans 21 and 22 overlap with each other, the cooling performance of the portable computer 1 is improved. That is, a plurality of exothermic bodies 16 are normally mounted on the printed circuit board 15, and the plural exothermic bodies 16 are generally collectively arranged in one or a few locations. By arranging the two cooling fans 21 and 22 in the vicinity of the mounting part of the exothermic bodies 16, the cooling performance of the portable computer 1 is improved.

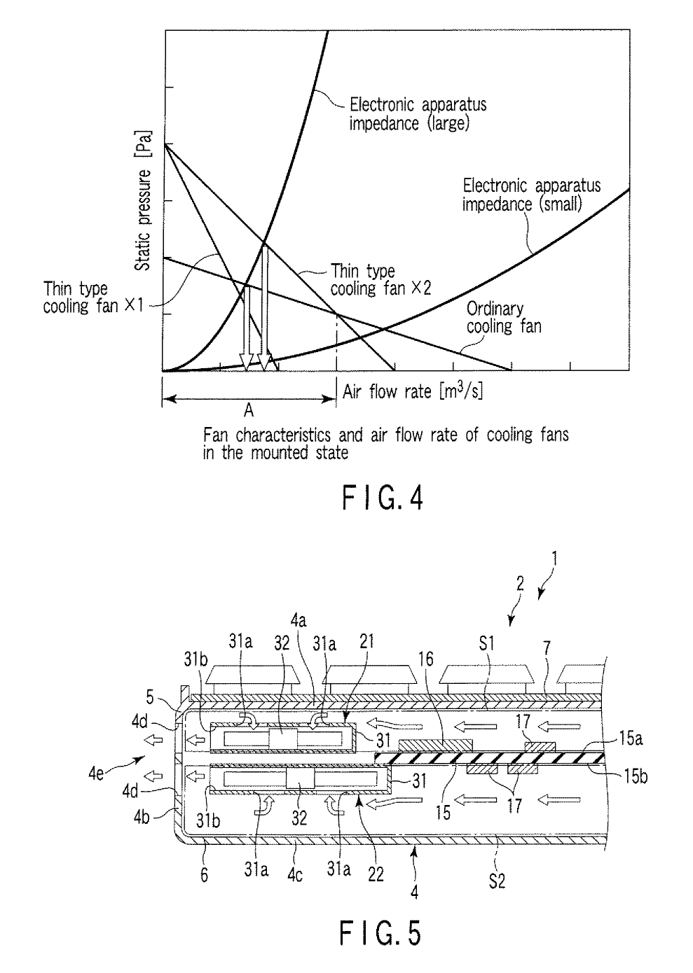

Next, the advantage of mounting two thin type cooling fans in place of mounting one cooling fan will be described below with reference to FIG. 4.

FIG. 4 is a graph showing experimental results of characteristics of the thin type cooling fans 21 and 22 according to this embodiment, and an experimental result of characteristics of an ordinary cooling fan (hereinafter referred to as an ordinary cooling fan) satisfying a predetermined relationship with the thin type cooling fans 21 and 22. Incidentally, the above predetermined relationship implies that the volume obtained when the two thin type cooling fans 21 and 22 are laid one on top of another is substantially equal to that of one ordinary cooling fan, and that a noise level (i.e., sound pressure level) observed when the two thin type cooling fans 21 and 22 are simultaneously operated is substantially equal to that of one ordinary cooling fan.

In a specific example, the size of each of the thin type cooling fans 21 and 22 is 50 mm×50 mm×6 mm, and the size of the ordinary cooling fan is 50 mm×50 mm×12 mm, and the noise level observed when both the two thin type cooling fans 21 and 22 are simultaneously driven, and the noise level of the ordinary cooling fan are both 38 db. In FIG. 4, “electronic apparatus impedance (small)” indicates an impedance characteristic of a 14 inch size all-in-one type portable computer, and “electronic apparatus impedance (large)” indicates an impedance characteristic of a 12 inch size thin type portable computer.

The inventors of the present invention have found that there are cases where it is more advantageous to mount two thin type cooling fans 21 and 22 than to mount one ordinary cooling fan in the same mounting space and with the same noise level. That is, it has been found that, as for the air flow rate in the electronic apparatus, i.e., the value of the point of intersection of the curve of the electronic apparatus impedance (i.e., ventilation resistance) with the straight line of the fan characteristic of the cooling fan, there is a region in which the air flow rate obtained when two thin type cooling fans 21 and 22 are mounted is larger than the air flow rate obtained when one ordinary cooling fan is mounted. More specifically, when the point of intersection of the electronic apparatus impedance curve with the fan characteristic line is within the region A in FIG. 4, the cooling performance is made higher when two thin type cooling fans 21 and 22 are mounted.

Summarizing the above description, (1) when two thin type cooling fans are compared with one cooling fan having the same volume as the sum of the volumes of the two thin type cooling fans, and having the same noise level as that of the two cooling fans in the same environment, and (2) if the two thin type cooling fans are used in a region (i.e., the region A in FIG. 4) in which when sum of exhaust air flows of the two thin type cooling fans is substantially equal to an exhaust air flow of the one cooling fan, the static pressure obtained by using the two thin type cooling fans is higher than that obtained by using the one cooling fan, mounting the two thin type cooling fans in place of the one cooling fan improves the cooling performance of the electronic apparatus. Incidentally, it is added here that the same tendency as that shown in FIG. 4 has been observed in cooling fans having various sizes.

In recent years, downsizing and high-density mounting of the portable electronic apparatus have been advanced, and the impedance of the portable electronic apparatus has therefore been raised. Mounting of two thin type cooling fans 21 and 22 as in this embodiment is particularly effective for portable electronic apparatuses for which downsizing and high-density mounting are desirable.

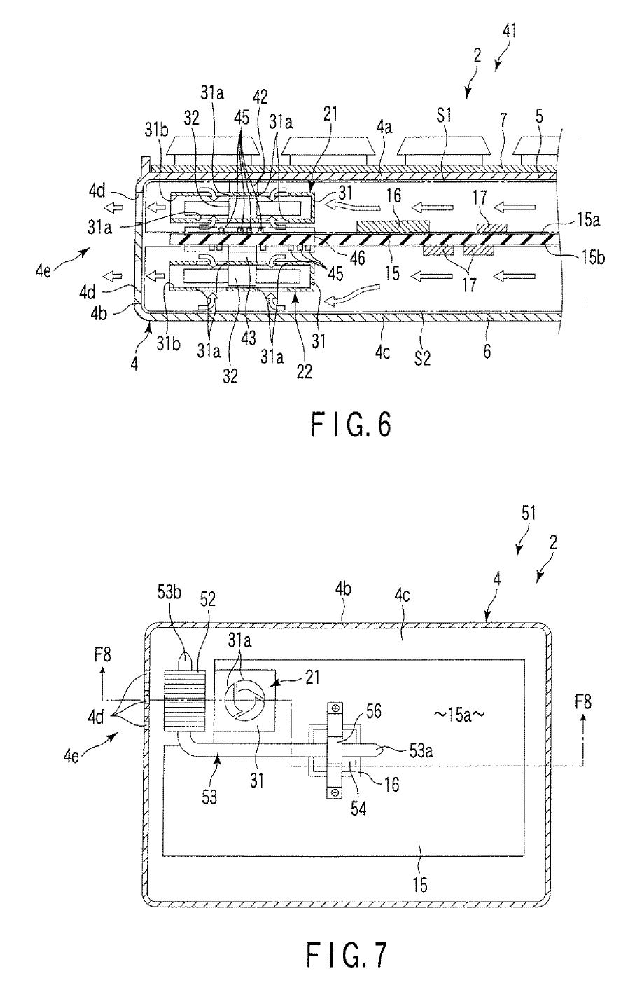

Next, a portable computer 41 which is a portable electronic apparatus according to a second embodiment of the present invention will be described below with reference to FIG. 6. Incidentally, configurations having the same functions as those of the portable computer 1 according to the first embodiment are denoted by the same reference symbols, and description of them are omitted.

A gap is provided between a first cooling fan 21 and an upper surface 15a of a printed circuit board 15. The first cooling fan 21 includes inlet ports 31a opposed to the printed circuit board 15. In this example of the first cooling fan 21, the cooling fan is fixed to a casing 4 by means of a holder 42. Incidentally, the first cooling fan 21 may be fixed to the printed circuit board 15 by a holder.

A gap is provided between a second cooling fan 22 and a lower surface 15b of the printed circuit board 15. The second cooling fan 22 includes inlet ports 31a opposed to the printed circuit board 15. In this example of the second cooling fan 22, the cooling fan is fixed to the printed circuit board 15 by means of a holder 43. Incidentally, the second cooling fan 22 may be fixed to the casing 4 by a holder.

A plurality of circuit components 45 are mounted in regions on the printed circuit board 15 opposed to the first and second cooling fans 21 and 22. Examples of the plural circuit components 45 are a semiconductor chip, a coil, and a capacitor. The plural circuit components 45 cooperate to form, for example, a power supply circuit 46.

According to a portable computer 41 having such a configuration, the board area of the printed circuit board 15 can be secured, and a high cooling performance can be realized, as in the case of the first embodiment.

The gap is provided between each of the first and second cooling fans 21 and 22 and the printed circuit board 15, whereby circuit components can be mounted in the region on the printed circuit board 15 opposed to each of the first and second cooling fans 21 and 22. As a result, the function of the printed circuit board 15 is further improved.

The first cooling fan 21 directly inhales air in the vicinity of the upper surface 15a of the printed circuit board 15 through the inlet ports 31a. The second cooling fan 22 directly inhales air in the vicinity of the lower surface 15b of the printed circuit board 15 through the inlet ports 31a. As a result, an exothermic body 16 and circuit components 17 and 45 which are mounted on the upper and lower surfaces 15a and 15b are efficiently cooled.

When the power supply circuit 46 is provided in the regions opposed to the inlet ports 31a of the first and second cooling fans 21 and 22, cooling of the power supply circuit 46 is promoted. The power supply circuit 46 is one of the parts in the portable computer 41 in which the temperature becomes high, and hence if the cooling of the power supply circuit 46 can be promoted, the cooling performance of the portable computer 41 is enhanced. The power supply circuit 46 includes small chip components, a coil, a capacitor, and the like, and hence it is not easy to attach a heat sink or the like thereto. Accordingly, if the power supply circuit can be subjected to forced cooling as in this embodiment, a rise in temperature of the power supply circuit 46 can be suppressed.

Incidentally, in this embodiment, although a gap is provided between each of the first and second cooling fans 21 and 22 and the printed circuit board 15, a gap may be provided between only one of the first and second cooling fans 21 and 22 and the printed circuit board 15.

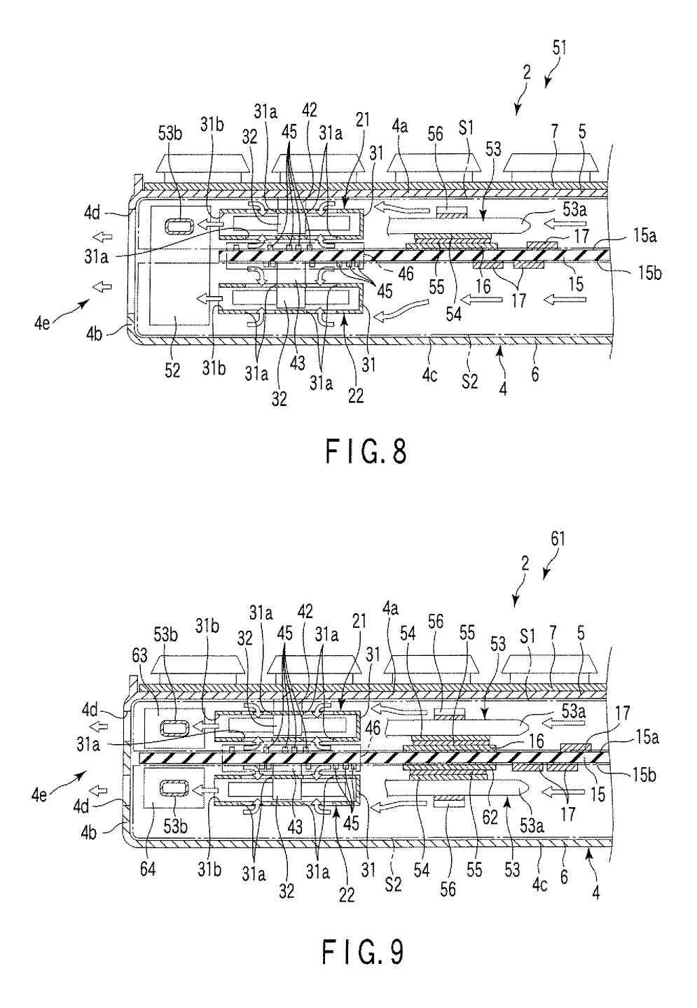

Next, a portable computer 51 which is a portable electronic apparatus according to a third embodiment of the present invention will be described below with reference to FIGS. 7 and 8. Incidentally, configurations having the same functions as those of the portable computers 1 and 41 according to the first and second embodiments are denoted by the same reference symbols, and description of them are omitted. As shown in FIG. 7, the portable computer 51 is provided with a heat radiation fin unit 52, a heat transfer member 53, and a heat conduction plate 54, in addition to the configuration according to the second embodiment.

As shown in FIG. 8, the heat radiation fin unit 52 is provided so as to allow it to extend from a part between an exhaust port 31b of a first cooling fan 21 and exhaust holes 4d of a casing 4 to a part between an exhaust port 31b of a second cooling fan 22 and the exhaust holes 4d of the casing 4. As a result, air discharged from the first cooling fan 21 is discharged to the outside of the casing 4 while taking heat from the heat radiation fin unit 52. Air discharged from the second cooling fan 22 is discharged to the outside of the casing 4 while taking heat from the heat radiation fin unit 52. The heat conduction plate 54 is provided above an exothermic body 16.

The heat conduction plate 54 is formed by using a material having high thermal conductivity, such as copper or an aluminum alloy. A heat transmission material 55 is interposed between the heat conduction plate 54 and the exothermic body 16. An example of a heat transmission material 55 is heat transmission grease or a heat transmission sheet.

An example of the heat transfer member 53 is a heat pipe. The heat transfer member 53 includes a heat receiving end section 53a and a heat radiating end section 53b. The heat receiving end section 53a is in contact with the heat conduction plate 54, and is thermally connected to the exothermic body 16 through the heat conduction plate 54 and the heat transmission material 55. The heat receiving end section 53a is pressed against a printed circuit board 15 by a pressing member 56. The heat radiating end section 53b is thermally connected to the heat radiation fin unit 52.

According to the portable computer 51 configured as described above, the board area of the printed circuit board 15 can be secured, and a high cooling performance can be realized, as in the first embodiment.

The heat radiation fin unit 52 forcedly cooled by the first and second cooling fans 21 and 22 is provided, and the exothermic body 16 is thermally connected to the heat radiation fin unit 52, whereby the cooling performance of the portable computer 51 is improved.

incidentally, it is sufficient if the heat radiation fin unit 52 is provided between one of the exhaust port 31b of the first cooling fan 21 and the exhaust port 31b of the second cooling fan 22 and the exhaust holes 4d of the casing 4. If the heat radiation fin unit 52 is opposed to the exhaust port 31b of the first cooling fan 21, and is also opposed to the exhaust port 31b of the second cooling fan 22, as in the case of this embodiment, the heat radiation fin unit 52 is forcedly cooled by the plural cooling fans 21 and 22, and hence the cooling performance of the portable computer 51 is improved.

Next, a portable computer 61 which is a portable electronic apparatus according to a fourth embodiment of the present invention will be described below with reference to FIG. 9. Incidentally, configurations having the same functions as those of the portable computers 1, 41, and 51 according to the first to third embodiments are denoted by the same reference symbols, and description of them are omitted. The portable computer 61 is provided with another exothermic body 62, first and second heat radiation fin units 63 and 64, two heat transfer members 53, and two heat conduction plate 54, in addition to the configuration according to the second embodiment.

An exothermic body 16 is mounted on an upper surface 15a of a printed circuit board 15. Another exothermic body 62 is mounted on a lower surface 15b of the printed circuit board 15. Another exothermic body 62 may be the same type of component as the exothermic body 16 or may be a component of a type different from the exothermic body 16.

As shown in FIG. 9, the first heat radiation fin unit 63 is arranged in an upper space S1. The first heat radiation fin unit 63 is provided between an exhaust port 31b of a first cooling fan 21 and exhaust holes 4d of a casing 4. Air discharged from the first cooling fan 21 is discharged to the outside of the casing 4 while taking heat from the first heat radiation fin unit 63. The first heat radiation fin unit 63 is thermally connected to the exothermic body 16 through a heat transfer member 53 and a heat conduction plate 54. The first heat radiation fin unit 63 overlaps with the printed circuit board 15 in the thickness direction of the printed circuit board 15.

The second heat radiation fin unit 64 is arranged in a lower space. The second heat radiation fin unit 64 is provided between an exhaust port 31b of a second cooling fan 22 and the exhaust holes 4d of the casing 4. Air discharged from the second cooling fan 22 is discharged to the outside of the casing 4 while taking heat from the second heat radiation fin unit 64. The second heat radiation fin unit 64 is thermally connected to the exothermic body 62 through a heat transfer member 53 and a heat conduction plate 54. The second heat radiation fin unit 64 overlaps with the printed circuit board 15 in the thickness direction of the printed circuit board 15. In other words, the first and second heat radiation fin units 63 and 64 interpose the printed circuit board 15 between them, and overlaps with each other in the thickness direction of the printed circuit board 15. Incidentally, the first and second heat radiation fin units 63 and 64 may overlap with each other only partly. The first and second heat radiation fin units 63 and 64 may not overlap with each other.

According to the portable computer 61 configured as described above, the board area of the printed circuit board 15 can be secured, and a high cooling performance can be realized, as in the first embodiment. That is, by mounting the two heat radiation fin units 63 and 64 separately on both the surfaces of the printed circuit board 15, it becomes unnecessary to form a cutout hole for mounting of the heat radiation fin unit in the printed circuit board 15. Accordingly, it is possible to secure a large board area of the printed circuit board 15 without being hindered by the heat radiation fin unit.

When the two heat radiation tin units 63 and 64 are separately arranged on both the surfaces of the printed circuit board 15, it is possible to sufficiently cool the exothermic body 16 mounted on the upper surface 15a of the printed circuit board 15 and the exothermic body 62 mounted on the lower surface 15b thereof.

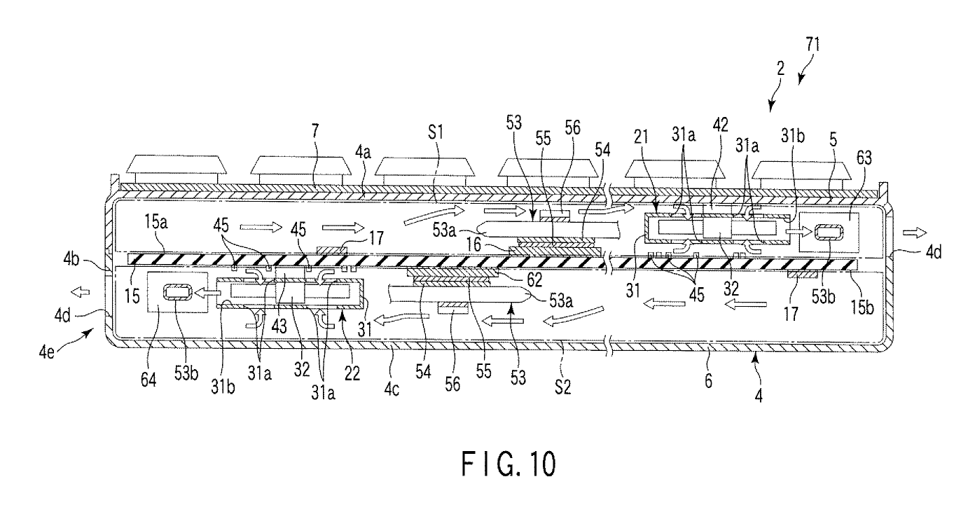

Next, a portable computer 71 which is a portable electronic apparatus according to a fifth embodiment of the present invention will be described below with reference to FIG. 10. Incidentally, configurations having the same functions as those of the portable computers 1, 41, 51, and 61 according to the first to fourth embodiments are denoted by the same reference symbols, and description of them are omitted.

As shown in FIG. 10, first and second cooling fans 21 and 22 overlap with a printed circuit board 15 in the thickness direction of the printed circuit board 15. The first and second cooling fans 21 and 22 do not overlap with each other.

With the portable computer 71 configured as described above, the board area of the printed circuit board 15 can be secured, and a high cooling performance can be realized as in the first embodiment.

The portable computers 1, 41, 51, 61, and 71 according to the first to fifth embodiments have been described above. Needless to say, the present invention is not limited to these. The constituent elements according to the above embodiments may be appropriately combined with each other to be implemented.

White certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A portable electronic apparatus comprising:
a casing provided with an exhaust hole part;
a printed circuit board contained in the casing;
an exothermic body mounted on the printed circuit board;
a first cooling fan contained in the casing; and
a second cooling fan contained in the casing, wherein
the casing contains an upper space extending above the printed circuit board and a lower space extending below the printed circuit board,
the first cooling fan is arranged in the upper space, and is provided with an inlet port opened in the upper space, and an exhaust port directed to the exhaust hole part of the casing, and
the second cooling fan is arranged in the lower space, and is provided with an inlet port opened in the lower space, and an exhaust port directed to the exhaust hole part of the casing.

2. The portable electronic apparatus according to claim 1, wherein
at least one of the first cooling fan and the second cooling fan overlaps with the printed circuit board in a thickness direction of the printed circuit board.

3. The portable electronic apparatus according to claim 2, wherein
both the first cooling fan and the second cooling fan overlap with the printed circuit board.

4. The portable electronic apparatus according to claim 3, wherein
the first cooling fan and the second cooling fan overlap with each other in the thickness direction of the printed circuit board.

5. The portable electronic apparatus according to claim 2, wherein
a gap is provided between at least one of the first cooling fan and the second cooling fan and the printed circuit board.

6. The portable electronic apparatus according to claim 5, wherein
the gap is provided between the printed circuit board and the cooling fan, the inlet port of which is opposed to the printed circuit board.

7. The portable electronic apparatus according to claim 1, further comprising:
a heat radiation fin unit provided between at least one of the exhaust port of the first cooling fan and the exhaust port of the second cooling fan and the exhaust hole part of the casing; and
a heat transfer member for thermally connecting the heat radiation fin unit to the exothermic body.

8. The portable electronic apparatus according to claim 1, wherein
the printed circuit board is decentered from a center of an internal space of the casing in the thickness direction of the printed circuit board.

9. The portable electronic apparatus according to claim 1, further comprising:
another exothermic body mounted on the printed circuit board;
a first heat radiation fin unit arranged in the upper space;
a second heat radiation fin unit arranged in the lower space;
a heat transfer member for thermally connecting one of the exothermic bodies to the first heat radiation fin unit; and
a heat transfer member for thermally connecting the other exothermic body to the second heat radiation fin unit.

10. A portable electronic apparatus comprising:
a casing provided with an exhaust hole part;
a printed circuit board contained in the casing;
an exothermic body mounted on the printed circuit board;
a first cooling fan which is contained in the casing, is opposed to the printed circuit board, and discharges air in the casing toward the exhaust hole part; and
a second cooling fan which is contained in the casing, is opposed to the printed circuit board from the opposite side to the first cooling fan, and discharges the air in the casing toward the exhaust hole part.
